(19) United States
(12) Patent Application Publication
(10) Pub. No.: US 2024/0030685 A1
(43) Pub. Date: Jan. 25, 2024

(54) SEMICONDUCTOR LASER DIODE

(71) Applicant: VISUAL PHOTONICS EPITAXY CO., LTD., Taoyuan City (TW)

(72) Inventors: Van-Truong DAI, Taoyuan City (TW); Yu-Chung CHIN, Taoyuan City (TW); Chao-Hsing HUANG, Taoyuan City (TW)

(21) Appl. No.: 18/223,852

(22) Filed: Jul. 19, 2023

(30) Foreign Application Priority Data
Jul. 19, 2022 (TW) 111127068
Nov. 11, 2022 (TW) 111143135

(51) Int. Cl. H01S 5/183; H01S 5/42; H01S 5/34

(52) U.S. Cl. CPC H01S 5/18361; H01S 5/423; H01S 5/3416; H01S 5/18305

(57) ABSTRACT

A semiconductor laser diode includes a substrate; a lower epitaxial region located on the substrate, wherein the lower epitaxial region includes a lower DBR layer; an active region located on the lower epitaxial region; and an upper epitaxial region located on the substrate, wherein the upper epitaxial region includes a lower DBR layer; wherein the lower DBR layer includes a P-type lower DBR region and the upper DBR layer includes an N-type upper DBR region.

### CROSS-REFERENCE TO RELATED APPLICATION

This application claims priority to Taiwan Application Serial Number 111127068, filed Jul. 19, 2022, and Taiwan Application Serial Number 111143135, filed Nov. 11, 2022, which is herein incorporated by reference in its entirety.

### BACKGROUND

### Field of Invention

The present invention relates to a semiconductor laser diode, and more particularly, to a one-dimensional or two-dimensional semiconductor laser diode array suitable for operation at high current density.

### Description of Related Art

Vertical cavity surface emitting laser diode (VCSEL) can be used as light sources for 3 dimensional (3D) sensing, optical communication, or infrared illumination.

Referring to FIG. 1a is a schematic diagram of an epitaxial structure of a VCSEL 100′ in the prior art. As shown in FIG. 1a, the VCSEL 100′ includes an N-type substrate 10′, a lower distributed Bragg reflector (DBR) layer 20′, an active region A′, and an N-type upper DBR layer 40′. The lower DBR layer 20′ or the upper DBR layer 40′ usually include of several ten layers. When the conductivity types of the substrate 10′ and the lower DBR layer 20′ are both N-type, the conductivity type of the upper DBR layer is P-type. The majority carriers of the P-type epitaxial layer are holes. The effective mass of the a hole is larger than that of an electron, and the mobility of a hole is lower than that of an electron, so the material resistance of the P-type epitaxial layer is larger than that of the N-type epitaxial layer.

FIG. 1b is a schematic diagram of an epitaxial structure of a VCSEL 101′ with a tunnel junction layer in the prior art. The substrate 10′ in FIG. 1b is also N-type, when a tunnel junction layer TJ′ is disposed between the active region A′ and the upper DBR layer 40′, all of the upper DBR layer 40′ are N-type layers.

### SUMMARY

For VCSEL die (not VCSEL arrays), each layer of the upper DBR layer and the lower DBR layer are of N-type can improve the light output power of the VCSEL die. However, for VCSEL arrays, the light output power is difficult to be increased or even impossible to be improved when the upper DBR layer and the lower DBR layer are of N-type.

It is well known that the material resistance of N-type materials is smaller than that of P-type materials. But in fact, the interface resistance between two adjacent N-type materials (such as high refractive index material and low refractive index material) could be very large. Taking the N-type DBR layer of AlₓGa₁₋ₓAs as an example, since the reflectivity of the N-type DBR layer needs to be close to 100%, there should be considerable difference in the refractive index between the high refractive index layer and low refractive index layer. For example, the aluminum content of the high refractive index layer (GaAs) is 0%, and the aluminum content of the low refractive index layer (Al_{0.8}Ga_{0.2}As) may be 80%. However, when the aluminum content of N-type AlₓGa₁₋ₓAs exceeds 40%, the band structure of AlₓGa₁₋ₓAs will transition from direct bandgap to indirect bandgap, causing electrons to be hindered when passing through the N-type lower DBR layer. However, P-type AlxGa₁₋ₓAs does not undergo a transition from a direct bandgap to an indirect bandgap, and the band structure of P-type AlxGa₁₋ₓAs is relatively flat, electrons can pass through the P-type AlGaAs layer more smoothly, and the current is easier to spread evenly.

In one embodiment, a semiconductor laser diode includes a substrate; a lower epitaxial region located on the substrate, wherein the lower epitaxial region includes a lower DBR layer; an active region located on the lower epitaxial region; and an upper epitaxial region located on the substrate, wherein the upper epitaxial region includes a lower DBR layer; wherein the lower DBR layer includes a P-type lower DBR region and the upper DBR layer includes an N-type upper DBR region.

In one embodiment, when the majority layers in the upper DBR layer are N-type, and the majority layers (or each layer) in the lower DBR layer are P-type, it results in reduced less light absorption in the upper epitaxial region, and lower interfaceresistance in the lower epitaxial region.

### BRIEF DESCRIPTION OF THE DRAWINGS

The invention can be more fully understood by reading the following detailed description of the embodiment, with reference made to the accompanying drawings as follows:

FIG. 1a is a schematic diagram of the epitaxial structure of a vertical cavity surface emitting laser diode (VCSEL) in the prior art;

FIG. 1b is a schematic diagram of the epitaxial structure of a VCSEL with a tunnel junction layer in the prior art;

FIG. 2a is a schematic diagram of the first tunnel junction layer disposed between the N-type substrate and the lower DBR layer, wherein the conductivity type of the lower DBR layer is P-type, according to an embodiment herein;

FIG. 2b is a schematic diagram of the first tunnel junction layer inserted into the lower DBR layer, wherein the lower DBR layer includes a P-type lower DBR region and an N-type lower DBR region, according to an embodiment herein;

FIG. 2c is a schematic diagram of the second tunnel junction layer inserted into the upper DBR layer, wherein the substrate is an N-type substrate, and the upper DBR layer includes a P-type upper DBR region and an N-type upper DBR region, according to an embodiment herein;

FIG. 3a is a schematic diagram of the P-type lower DBR layer and the P-type substrate, according to an embodiment herein;

FIG. 3b is a schematic diagram of inserting the first tunnel junction layer into the lower DBR layer and inserting the second tunnel junction layer into the upper DBR layer, wherein the substrate is a P-type substrate, according to an embodiment herein;

FIG. 4a is a schematic diagram of an N-type lower ohmic contact layer disposed on the substrate, according to an embodiment herein.

FIG. 4b is a schematic diagram of an N-type ohmic contact electrode disposed below the substrate, according to an embodiment herein;

FIG. 4c is a schematic diagram of an back electrode, according to an embodiment herein; and

FIG. 5 shows the L-I-V curves for Embodiment 1 and the control group.

### DETAILED DESCRIPTION

The embodiment of the present invention is described in detail below with reference to the drawings and element symbols, such that persons skilled in the art is able to implement the present application after understanding the specification of the present invention.

Specific examples of components and arrangements are described below to simplify the present invention. Of course, these are merely examples and the examples are not intended to limit the scope of the present invention. For example, when a description refers to one layer above another, it may include embodiments where the layer is in direct contact with the other layer or may include embodiments where other elements or epitaxial layers are formed between the two layers and the two layers are not in direct contact. In addition, repeated reference numerals and/or notations may be used in different embodiments, these repetitions are used to describe some embodiments simply and clearly and do not represent a specific relationship between the different embodiments and/or structures discussed.

Further, spatially relative terms, such as “underlying,” “below,” “lower,” “overlying,” “above,” “upper” and the like, may be used herein for ease of description to describe one element or feature's relationship to another element(s) or feature(s) as illustrated in the figures and/or drawings. The spatially relative terms are intended to encompass different orientations of the device in use or operation in addition to the orientation depicted in the figures.

The description of the present invention provides different embodiments to illustrate the technical features of different implementations. For example, “some embodiments” referred to throughout the specification means that the specific features, structures, or characteristics described in the embodiments are included in at least one embodiment. Thus, appearances of the phrase “in some embodiments” in different passages throughout the specification are not necessarily the same embodiments.

Furthermore, the particular features, structures, or characteristics may be combined in any suitable manner in one or more embodiments. Further, for the terms “including”, “having”, “with”, “wherein” or the foregoing transformations used herein, these terms are similar to the term “comprising” to include corresponding features.

In addition, a “layer” may be a single layer or a plurality of layers; and “a portion” of an epitaxial layer may be one layer of the epitaxial layer or a plurality of adjacent layers.

In current technology, the laser diode can be selectively provided with a buffer layer according to actual needs, and in some examples, the material of the buffer layer and the substrate can be the same. Also, whether the buffer layer is provided or not is not substantially related to the technical characteristics described in the following embodiments and the effects of the following embodiments. Therefore, in order to illustrate briefly, the following embodiments only use a laser diode with a buffer layer as an illustrative example and do not repeat the laser diode without a buffer layer. That is to say, if the following embodiments are replaced with a laser diode without a buffer layer, it is also applicable.

Hereinafter, if the DBR layer is called, the DBR layer refers to the upper DBR layer, the lower DBR layer, or both. The DBR layer is a periodic structure in which low refractive index layers and high refractive index layers are alternately stacked to form a structure with high reflectivity. The DBR layer may include several to dozens of pairs of alternating structures.

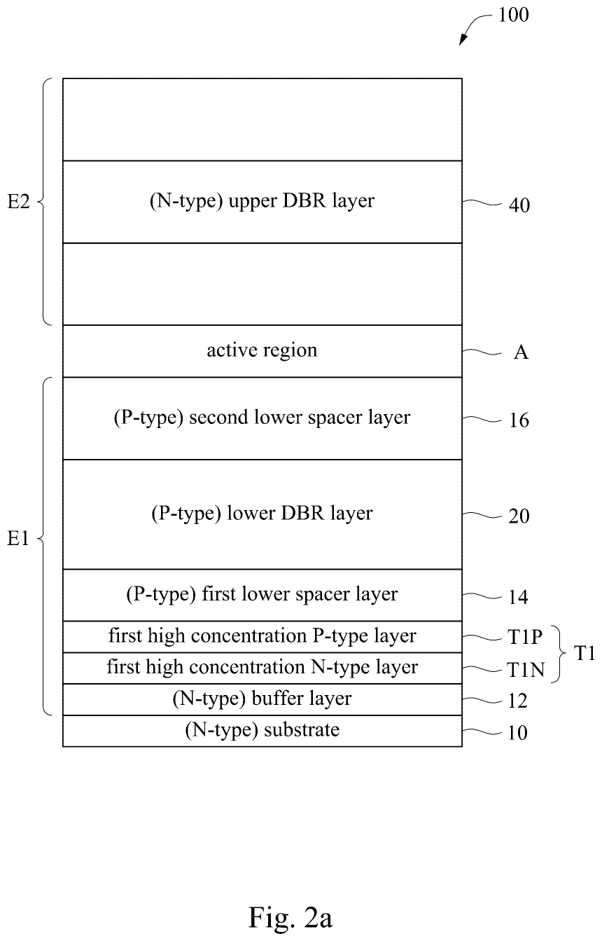

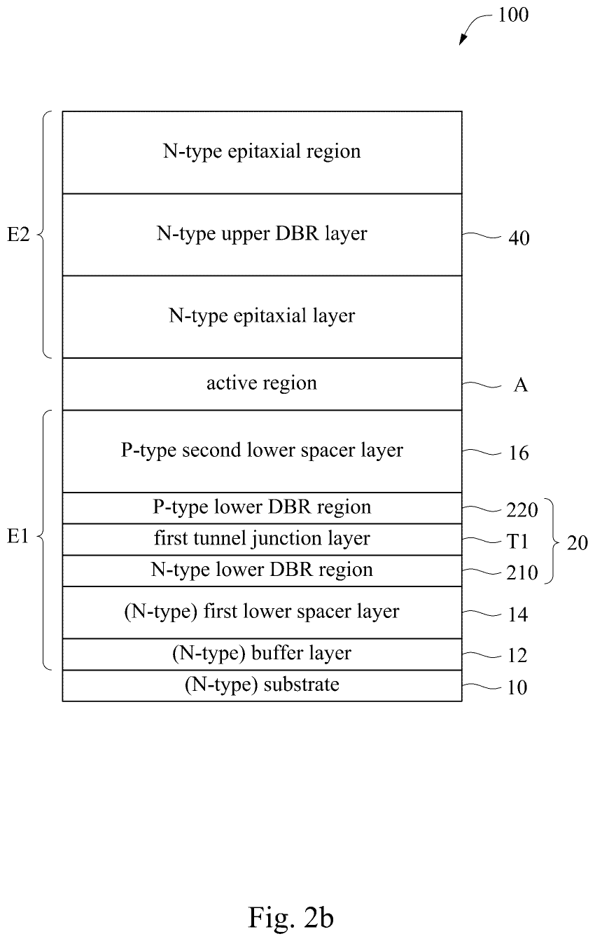

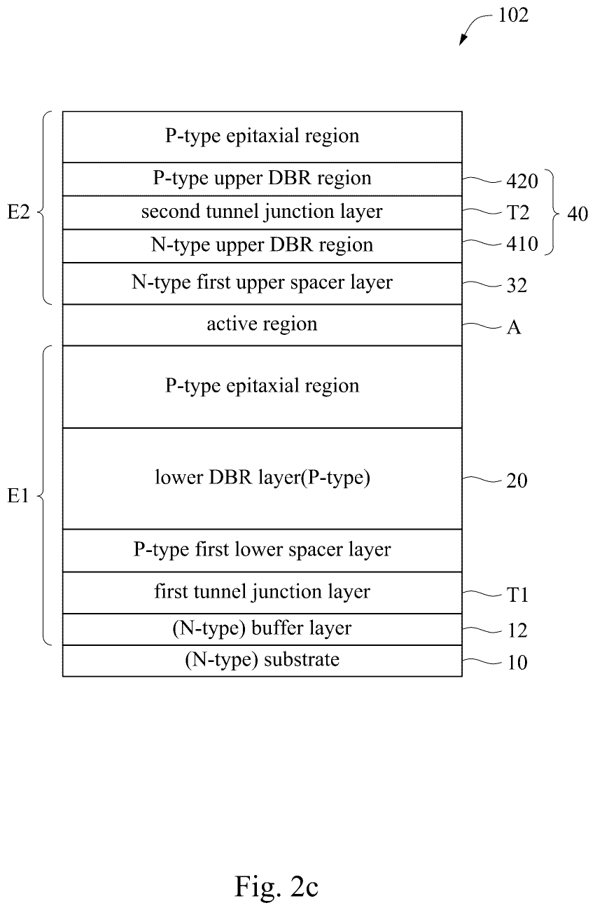

The embodiments herein show surface-emitting laser diode epitaxial structure such as VCSEL. As shown in FIG. 2a, the main structure of each embodiment includes a substrate 10, a lower epitaxial region E1, an active region A, and an upper epitaxial region E2, wherein the lower epitaxial region E1 and the upper epitaxial region E2 include the lower DBR layer 20 and the upper DBR layer 40, respectively. The active region A comprises one or more active layers. One active layer can include a quantum well layer or multiple quantum well layers. When the active region contains multiple active layers, adjacent active layers are connected in series through tunneling junction layer, where the tunneling junction layer is maintained at reverse bias.

The conductivity type of a portion (some of the alternating structures) or all (all of the alternating structures) of the lower DBR layer 20 can be P-type. The conductivity type of a portion (some of the alternating structures) or all (all of the alternating structures) of the upper DBR layer 40 can be N-type. The substrate 10 may be an N-type substrate, a P-type substrate or a semi-insulating substrate.

### Embodiment 1 (N-Type Substrate and P-Type Lower DBR Layer)

In the epitaxial structure 100 of FIG. 2a, the substrate 10 is an N-type substrate, and an N-type buffer layer 12, a first high concentration N-type layer T1N, a first high concentration P-type layer T1P, a P-type first lower spacer layer 14 and a P-type lower DBR layer 20 are formed on the N-type substrate. With this arrangement, each layer in the lower DBR layer 20 is P-type. In addition, each layer in the upper DBR layer 40 is N-type.

For example, a P-type second lower spacer layer 16 or other suitable P-type epitaxial layers may be disposed on the lower DBR layer 20 of FIG. 2a.

### Embodiment 2 (N-Type Substrate and a Portion of the Lower DBR Layer is P-Type)

In the epitaxial structure 101 of FIG. 2b, the substrate 10 is an N-type substrate. A portion of the lower DBR layer (N-type lower DBR region 210 of FIG. 2b) is first formed on the N-type first lower spacer layer 14; next, the first tunnel junction layer T1 and another portion of the lower DBR layer (P-type lower DBR region 220) are formed on N-type lower DBR region 210. With this arrangement, the portion of the lower DBR layer 20 close to the N-type substrate is the N-type lower DBR region 210, wherein the N-type first lower spacer layer 14 is selectively formed on the N-type buffer layer 12.

### Embodiment 3 (N-Type Substrate and a Portion of the Upper DBR Layer is N-Type)

As shown in FIG. 2c, the epitaxial structure 102 includes a first tunnel junction layer T1 and a second tunnel junction layer T2. The arrangement method and principle for the second tunnel junction layer T2 are the same as those for the first tunnel junction layer T1, please refer to the above description. In FIG. 2c, the N-type first upper spacer layer 32 is selectively formed on the active region A Embodiment 4 (P-Type Substrate)

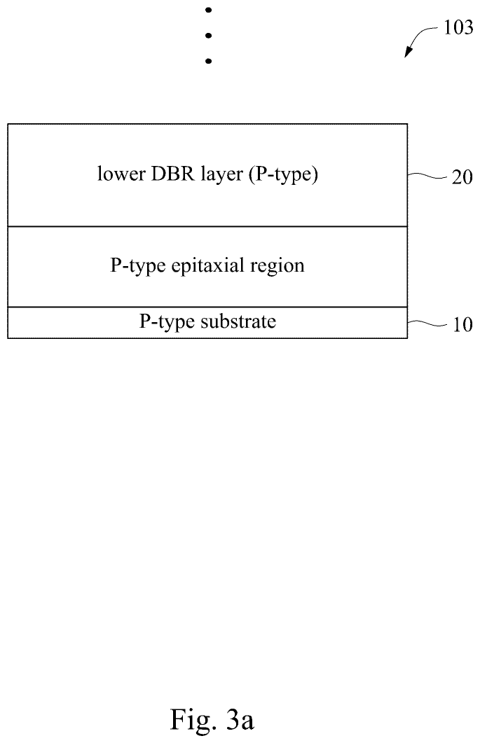

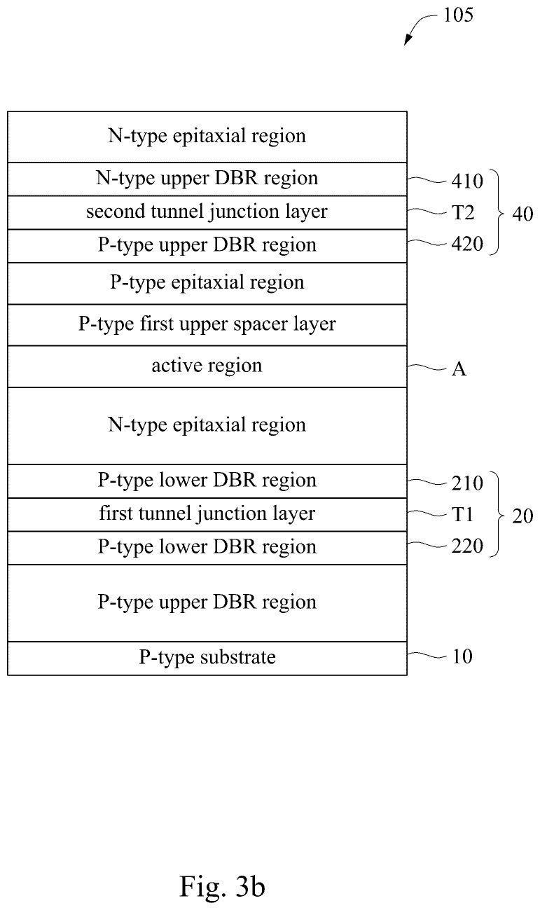

In the epitaxial structure 103 of FIG. 3a, since the conductivity types of the substrate 10 and the lower DBR layer 20 are both P-type, there is no need to provide a tunnel junction layer between them. For the implementation of the epitaxial stack structure on the P-type lower DBR layer 20, please refer to the relevant paragraphs herein.

In the epitaxial structure 105 of FIG. 3b, the lower DBR layer 20 and the upper DBR layer 40 can be provided with a first tunnel junction layer T1 and a second tunnel junction layer T2 respectively. It should be noted that, since the substrate 10 is a P-type substrate, the conductivity type of the portion of the lower DBR layer 20 and the upper DBR layer 40 in FIG. 3b that is closest to the substrate 10 (that is, the P-type lower DBR region 220 and the P-type upper DBR region 420) will be P-type.

In some embodiments, the substrate 10 may also be a semi-insulating substrate, the N-type epitaxial layer or the P-type epitaxial layer can be directly formed on the semi-insulating substrate. For the epitaxial stack structure that can be formed on the N-type epitaxial layer or the P-type epitaxial layer, please refer to the description in the relevant paragraphs herein. A relatively thick buffer layer can be disposed on the semi-insulating substrate.

In some embodiments, the material of the substrate 10 is GaAs or Ge (germanium).

In some embodiments, the material of the high refractive index layers of the DBR layer may contain low aluminum content such as GaAs or AlGaAs; the material of the low refractive index layers of the DBR layer may contain high aluminum content such AlGaAs. The aforementioned materials may be P-type or N-type materials.

In some embodiments, the “high refractive index layers” of some alternating structures in the N-type upper DBR region 410 or the N-type lower DBR region 210 may be “N-type GaAs” or “N-type AlGaAs”, and the “low refractive index layer” may be “N-type InAlGaP” or “N-type AlGaAs”.

In some embodiments, an bandgap graded layer is further disposed between the high refractive index layer and the low refractive index layer. The bandgap graded layer is AlGaAs.

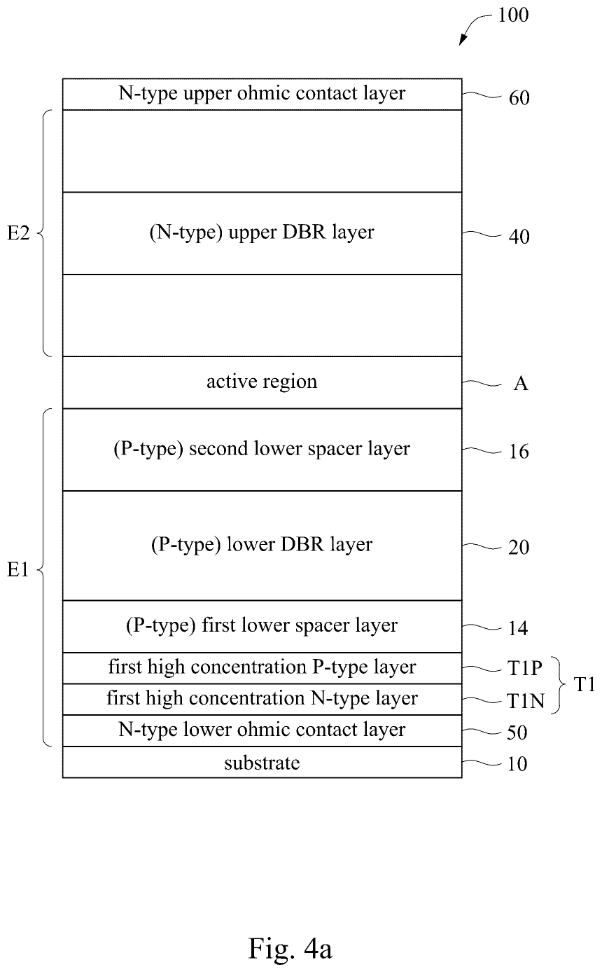

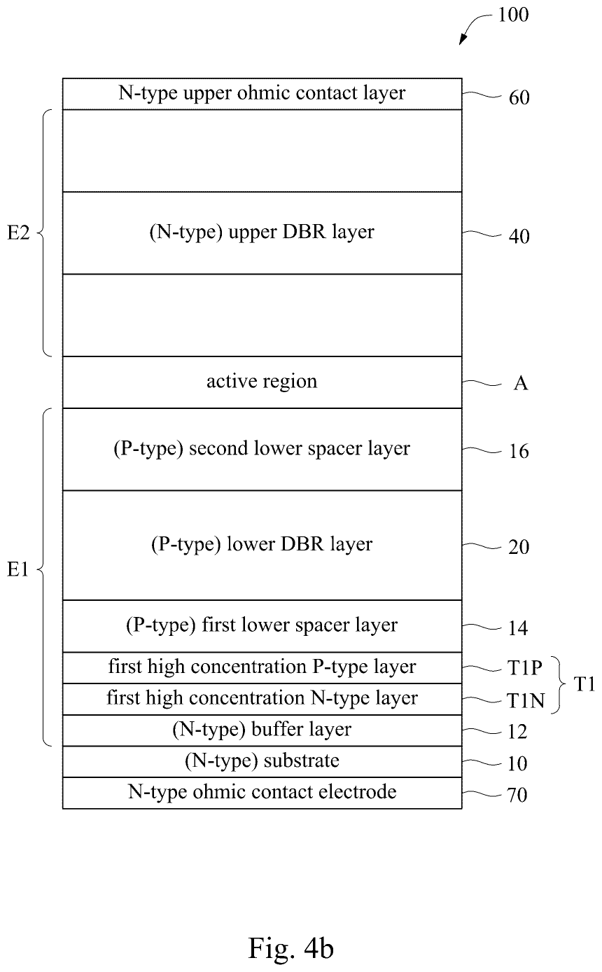

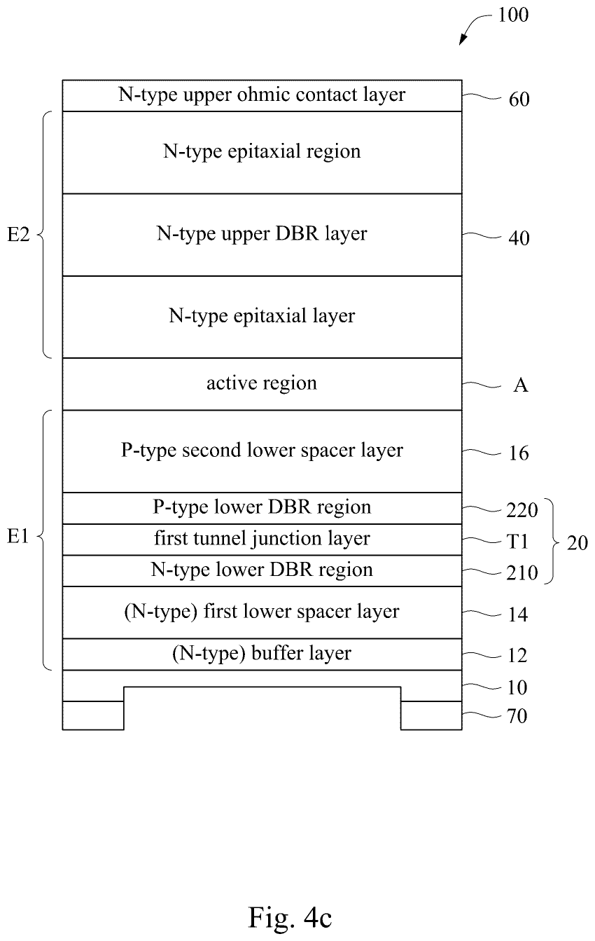

Referring to FIG. 4a, the top-emitting VCSEL can incorporate an N-type buffer layer, which can be utilized as an N-type lower ohmic contact layer 50, and the substrate 10 can be an N-type substrate, a P-type substrate, or a semi-insulating substrate. The N-type lower ohmic contact layer 50 can be disposed above the substrate 10 to form an ohmic contact electrode on the N-type lower ohmic contact layer 50. Additionally, an N-type upper ohmic contact layer 60 needs to be formed above the upper DBR layer 40 to form an ohmic contact electrode (not shown in the figure) on the N-type upper ohmic contact layer 60. Furthermore, when the substrate is a N-type substrate, an ohmic contact electrode 70 can be directly formed beneath the N-type substrate (referred to as a back electrode), as shown in FIG. 4b.

Similarly, the N-type buffer layer of a bottom-emitting VCSEL can also be utilized as an N-type lower ohmic contact layer 50, and the substrate 10 can also be an N-type substrate, a P-type substrate, or a semi-insulating substrate. The N-type lower ohmic contact layer 50 can be disposed above the substrate to form an ohmic contact electrode on the N-type lower ohmic contact layer 50. Additionally, an N-type upper ohmic contact layer 60 needs to be formed above the upper DBR layer 40 to form an ohmic contact electrode (not shown in the figure) on the N-type upper ohmic contact layer 60. Furthermore, when the substrate is a N-type substrate, an ohmic contact electrode 70 can be directly formed beneath the N-type substrate (referred to as a back electrode). The N-type lower ohmic contact layer 50 has a smaller lateral resistance, which helps to further reduce the resistance in the lower epitaxial region of the VCSEL. It should be noted that if it is necessary to mitigate or minimize light absorption by substrate (e.g., when the substrate is N-type or P-type or the substrate's bandgap absorbs the emitted wavelength), a portion or all of the substrate 10 can be further removed, or the thickness of the substrate can be reduced (which helps improve the output power of bottom-emitting VCSELs). When the back electrode 70 is formed beneath the substrate, it is important to avoid blocking the light and affecting the output power. Therefore, one embodiment of the back electrode 70 can be referred to as shown in FIG. 4c, but is not limited to this configuration.

In one embodiment, the semiconductor laser may be a semiconductor laser (or semiconductor laser array) with a common anode structure wherein the upper DBR layer is N-type and the lower DBR layer is P-type. The semiconductor laser can be a top-emitting type or a bottom-emitting type vertical cavity surface emitting laser.

The surface-emitting laser diode epitaxial wafer fabricated according to the embodiments herein is suitable to be fabricated into a one-dimensional (1D) or two-dimensional (2D) vertical cavity surface emitting laser arrays that can be operated under high current density or high power density, or is suitable to be fabricated into vertical cavity surface emitting laser arrays with high array density.

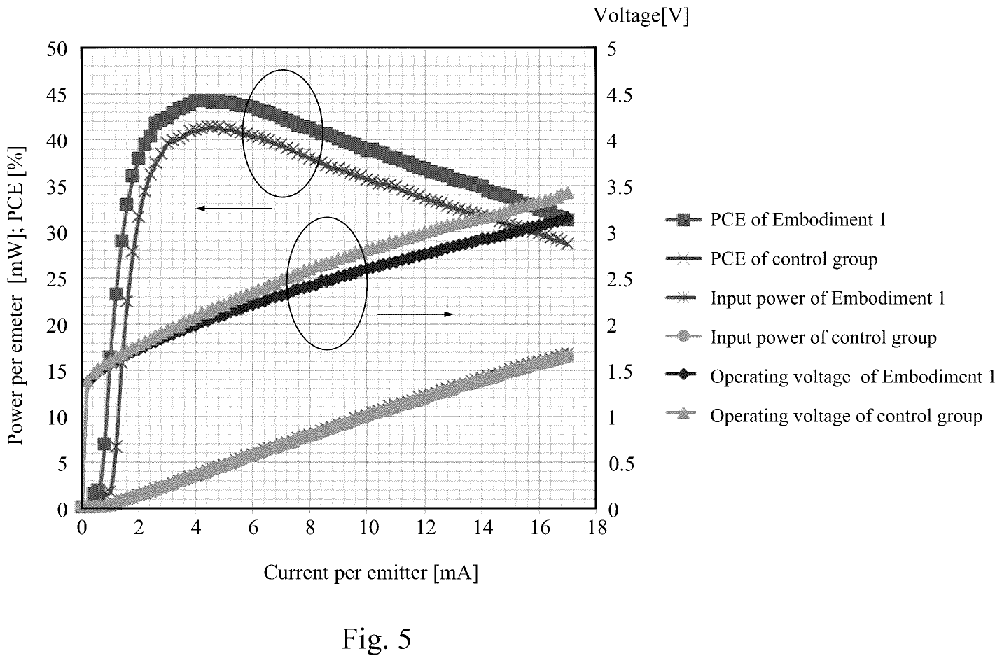

FIG. 5 shows the L-I-V curves for Embodiment 1 and the control group. Both Embodiment 1 and the control group are 940 nm VCSEL array, each having 85 emitters. The distance between any two adjacent emitters (center to center) is about 40 μm, and the bottom DBR layer is composed of GaAs high refractive index layer and AlGaAs low refractive index layer. The current in FIG. 5 are the current of each emitter.

Embodiment 1 is the epitaxial structure of FIG. 2a. In this structure, the first high concentration N-type layer T1N is GaAs doped with Tellurium, and the first high concentration P-type layer T1P is GaAs doped with Carbon. The lower DBR layer consists of alternating stacks of P-type GaAs and P-type AlGaAs, while the upper DBR layer consists of alternating stacks of N-type GaAs and N-type AlGaAs.

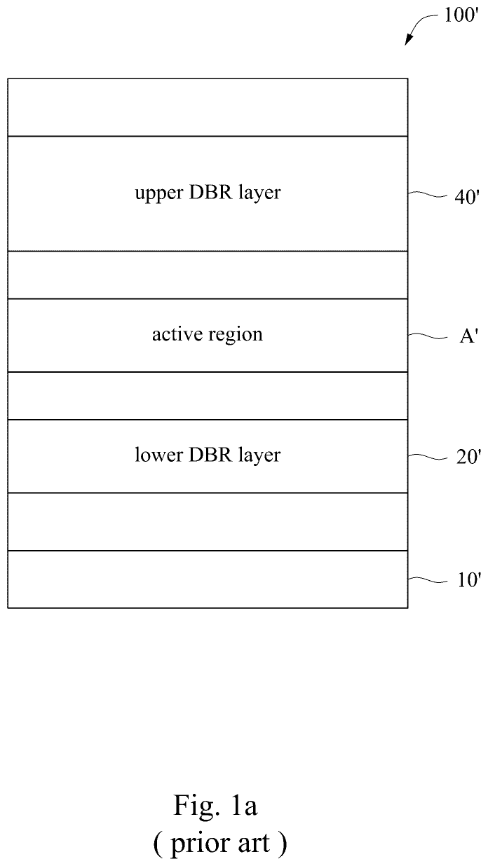

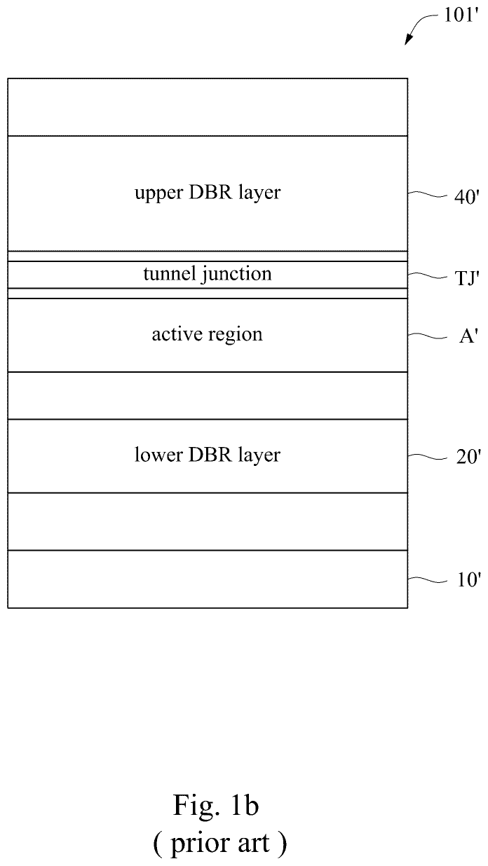

The control group is an epitaxial structure of prior art shown in FIG. 1a. The N-type lower DBR layer consists of alternating stacks of N-type GaAs and N-type AlGaAs. The P-type upper DBR layer consists of alternating stacks of P-type GaAs and P-type AlGaAs.

As can be seen from FIG. 5, both Embodiment 1 and the control group were both subjected to the same input current, but Embodiment 1 has a lower operating voltage, indicating that the resistance of the lower DBR layer is lower. Therefore, the power conversion efficiency of Embodiment 1 is significantly better than that of the control group.

The above are only preferred embodiments for explaining the present invention, and are not intended to limit the present invention in any form. Therefore, any modification or change related to the present invention made under the same spirit of the invention should still be included in the intended protection scope of the present invention.

What is claimed is:

1. A semiconductor laser diode, comprising:
a substrate;
a lower epitaxial region located on the substrate, wherein the lower epitaxial region comprises a lower distributed Bragg reflector (DBR) layer;
an active region located on the lower epitaxial region; and
an upper epitaxial region located on the active region, wherein the upper epitaxial region comprises an upper DBR layer;
wherein the lower DBR layer comprises a P-type lower DBR region and the upper DBR layer comprises an N-type upper DBR region.

2. The semiconductor laser diode of claim 1, wherein the semiconductor laser diode is a semiconductor laser diode array.

3. The semiconductor laser diode of claim 1, wherein the substrate is an N-type substrate, a P-type substrate, or a semi-insulating substrate.

4. The semiconductor laser diode of claim 1, further comprising a first tunnel junction layer, wherein the first tunnel junction layer is disposed between the substrate and the lower DBR layer or in the lower DBR layer.

5. The semiconductor laser diode of claim 1, wherein the lower epitaxial region further comprises a first tunnel junction layer, the first tunnel junction layer is disposed between the substrate and the lower DBR layer, the first tunnel junction layer comprises a high concentration P-type layer and a high concentration N-type layer, and the high concentration N-type layer is between the substrate and the high concentration P-type layer.

6. The semiconductor laser diode of claim 1, wherein the lower DBR layer further comprises a first tunnel junction layer and the N-type lower DBR region, the first tunnel junction layer is disposed between the N-type lower DBR region and the P-type lower DBR region, the N-type lower DBR region is closer to the substrate than the P-type lower DBR region.

7. The semiconductor laser diode of claim 1, wherein the active region comprising one or more active layers.

8. The semiconductor laser diode of claim 1, wherein the material of the substrate is GaAs or Ge.

9. The semiconductor laser diode of claim 1, wherein the upper DBR layer or the lower DBR layer comprises a high refractive index layer and a low refractive index layer, the material of the high refractive index layer is GaAs or AlGaAs, and the material of the low refractive index layer is AlGaAs.

10. The semiconductor laser diode of claim 1, wherein the upper DBR layer or the lower DBR layer comprises a high refractive index layer, a bandgap graded layer, and a low refractive index layer, the bandgap graded layer is disposed between the high refractive index layer and the low refractive index layer.

11. The semiconductor laser diode of claim 1, wherein the lower DBR layer further comprises an N-type lower DBR region, the N-type lower DBR region comprises a plurality of N-type alternating structures, at least one N-type alternating structure comprises a high refractive index layer, a bandgap graded layer, and a low refractive index layer.

12. The semiconductor laser diode of claim 11, wherein the material of the low refractive index layer is AlGaAs, and the material of the high refractive index layer is GaAs or AlGaAs, and the material of the bandgap graded layer is AlGaAs.

13. The semiconductor laser diode of claim 1, wherein the N-type upper DBR region comprises a plurality of N-type alternating structures, at least one the N-type alternating structure comprises a high refractive index layer, a bandgap graded layer, and a low refractive index layer.

14. The semiconductor laser diode of claim 13, wherein the material of the low refractive index layer is AlGaAs, and the material of the high refractive index layer is GaAs or AlGaAs, and the material of the bandgap graded layer is AlGaAs.

15. The semiconductor laser diode of claim 4, wherein the semiconductor laser diode is a top-emitting vertical cavity surface emitting laser and the substrate is an N-type substrate, a P-type substrate, or a semi-insulating substrate, wherein the semiconductor laser diode further includes an N-type ohmic contact layer, where the N-type ohmic contact layer is formed on the substrate.

16. The semiconductor laser diode of claim 4, wherein the semiconductor laser diode is a top-emitting vertical cavity surface emitting laser and the substrate is an N-type substrate, wherein the semiconductor laser diode further includes an N-type ohmic contact electrode, where the N-type ohmic contact electrode is formed below the N-type substrate.

17. The semiconductor laser diode of claim 4, wherein the semiconductor laser diode is a bottom-emitting vertical cavity surface emitting laser and the substrate is an N-type substrate, a P-type substrate, or a semi-insulating substrate, wherein the semiconductor laser diode further includes an N-type ohmic contact layer, where the N-type ohmic contact layer is formed on the substrate.

18. The semiconductor laser diode of claim 4, wherein the semiconductor laser diode is a bottom-emitting vertical cavity surface emitting laser and the substrate is an N-type substrate, wherein the semiconductor laser diode further includes an N-type ohmic contact electrode, where the N-type ohmic contact electrode is formed below the N-type substrate.

19. The semiconductor laser diode of claim 1, wherein the semiconductor laser diode is a top-emitting vertical cavity surface emitting laser or a bottom-emitting vertical cavity surface emitting laser.
